(19) United States
(12) Patent Application Publication
(10) Pub. No.: US 2010/0141049 A1
(43) Pub. Date: Jun. 10, 2010

(54) INTELLECTUAL POWER SAVING SEITCHING ASSEMBLY

(76) Inventor: Ying-Liang Shiu, Taoyuan (TW)

Correspondence Address: Ying-Liang Shiu, 235 Chung-Ho Box 8-24, Taipei, 235, TW

(21) Appl. No.: 12/704,535

(22) Filed: Feb. 12, 2010

Related U.S. Application Data
(62) Division of application No. 12/123,465, filed on May 20, 2008.

(51) Int. Cl. H03K 17/00

(52) U.S. Cl. 307/131

(57) ABSTRACT

An intellectual power saving switching assembly connected between an external AC power input and a device to be monitored for automatically turning on or turning off power supplied to the device to be monitored. The assembly includes a power source; an AC power input; a switchable AC power switch device; at least one current detector for detecting current flowing into the device to be monitored by direct detection or indirection detection; at least one AC power output end for supplying power from the current detector to the device to be monitored; a signal detecting transceiver for detecting an actuation signal from a remote controller; and a logic electronic circuit capable of receiving standby signals from the current detector and a far end actuation signals so as to perform status determination for interrupting or transferring the current from the AC power input to the device to be monitored.

The present invention is a divisional patent application of the U.S. patent application Ser. No. 12/123,465 which is assigned to the inventor (also the applicant of the present invention). The original filed claim is request to divide into two applications for restriction reasons. In this application, the claims 1 and 11 in the original claims are claimed.

### FIELD OF THE INVENTION

The present invention relates to power saving devices, and particularly to an intellectual power saving switching assembly which can reduce the power consumption as a device is at a standby mode, which is especially suitable for the current high energy cost age. The present invention can automatically actuate and de-actuate the power supply of a device to be monitored. The user is unnecessary to operate it manually. Thus the present invention is a practical and useful power saving device.

### BACKGROUND OF THE INVENTION

Currently, the price of energy increases day by day and this trend will be continued for a long time. Therefore, all nations make their best to develop power saving device.

Currently the electric devices or electronic devices are widely used all over the world, but these devices still consume power as they are not used because the electric wires still connect the power sources without being interrupted. Although for short time period, this power consumption is low, for the long time, accumulation of the power consumption will become a great burden to users since they make a great increment to the fee for electric power. Currently habitually, people will not draw plugs from receptacles for most electric and electronic devices, such as TVs, DVD players, refrigerators, air conditions, stereos, etc. From a report of International energy bureau, it is found that power consumption from the standby devices occupy 3 to 11% of the overall power consumption. Thus, if people habitually removes the plugs from the receptacles, it will make a large power saving in electric power fees.

In one improvement structure, made by University of Essex, U. K., an intellectual plug is developed. The plug is embedded with a sensor. If the electric or electronic devices in house are not used, an alarm emits signals to a central controller so as to turn off the related devices. In the estimation, the cost for the improvement device is about 2 U.S. dollars.

Current used auto-interrupting switch detects the current load of a device to be monitored. The control circuit determines the standby signal from the detector and then turn off the power source to the device to be monitored so as to have the function of auto-turning off the device to be monitored. However in this device, if it is desired to re-actuate the device to be monitored, the user must turn on the device manually by re-connecting the power wire and thus the operation is inconvenient.

However above-mentioned improvement device is not matched to the human habit and the user will feel inconvenient. This is because after disconnecting the power, the user must insert the plug to the receptacle manually, but this cannot be accepted by users.

In another prior art, a detection alert switch is used to detect the current load of a device to be monitored. The standby signal from the device to be monitored is transferred to the switch through a control circuit and then the signal is converted into light or sound to alert the user about the power consumption of the device to be monitored. Then the user can remove the plug of the device to be monitored so as to avoid undesired power consumption. However if the device to be monitored is to be actuated, it must be turned on manually by reinserting the plug into the receptacle. This prior art cannot de-actuate the power immediately, while the user must turn off the device by himself/herself. The operation is inconvenient.

Above mentioned prior art uses the power from the device to be monitored, although the power needed is small, it still induces power consumption.

In summary, the prior arts need to actuate the device to be monitored manually, it is inconvenient and the power from the device to be monitored is still supplied to the prior art switching devices so as to induce extra power consumption. Furthermore, the device to be monitored must be actuated by users, this makes trouble to users.

### SUMMARY OF THE INVENTION

Accordingly, the object of the present invention is to provide an intellectual power saving switching assembly, wherein the present invention causes no current consumption in standby mode so that no power consumption is in standby mode and thus power is saved. This is especially important in current high power cost age. Secondly, the present invention provides a function for auto-turning on an AC power without manually operation. Thus it is a power saving device with a practical usage. Thirdly, the present invention can turn off the AC power input automatically. Lastly, the device to be monitored is turned on by the current used remote controller without needing manual operation.

To achieve above object, the present invention provides an intellectual power saving switching assembly connected between an external AC power input and a device to be monitored for automatically turning on or turning off power supplied to the device to be monitored, comprising: a power source supplying power to all elements of the switching assembly; an AC power input connected to an external power source used to supplying power to the device to be monitored; a switchable AC power switch device connected to the AC power input; at least one current detector for detecting current flowing into the device to be monitored by direct detection or indirection detection; when the device to be monitored is turned off and thus is in a standby mode, the current detector will detect a corresponding standby signal; at least one AC power output end connected between the current detector and the device to be monitored for supplying power from the current detector to the device to be monitored; a signal detecting transceiver for detecting an actuation signal from a remote controller to actuate the device to be monitored; and a logic electronic circuit capable of receiving standby signals from the current detector and a far end actuation signal from the signal detecting transceiver so as to perform status determination for operating the switchable AC power switch device so as to interrupt or transfer the current from the AC power input to the device to be monitored.

The various objects and advantages of the present invention will be more readily understood from the following detailed description when read in conjunction with the appended drawing.

### BRIEF DESCRIPTION OF THE DRAWINGS

FIG. 1 is a block diagram for the element of the present invention.

FIG. 2 shows the detail structure of the present invention.

FIG. 3 shows that two devices to be monitored are equipped in the present invention.

FIG. 4 shows the second embodiment of the present invention.

### DETAILED DESCRIPTION OF THE INVENTION

In order that those skilled in the art can further understand the present invention, a description will be provided in the following in details. However, these descriptions and the appended drawings are only used to cause those skilled in the art to understand the objects, features, and characteristics of the present invention, but not to be used to confine the scope and spirit of the present invention defined in the appended claims.

The present invention provides an intellectual power saving switch which can turn on and turn off the power to a device. The switch assembly of the present invention can be used in a power receptacle embedding in a wall, a receptacle with one or more insertion slots with an extension wire, or has a form of an adaptor which is used with other conventional receptacle so as to have the function of the present invention, or the present invention can be integrated into a device to be monitored. However all these or other like usages are all within the scope and spirit of the present invention.

In the present invention, the load current and signals from the remote controller are detected so as to automatically turn on or turn off the external power source. The present invention can be realized with a form of a receptacle or a form of a plug or a form of a connector, or may be integrated into a circuit as a part thereof, or the present invention can be integrated into a device to be monitor so as to have the function disclosed in the present invention.

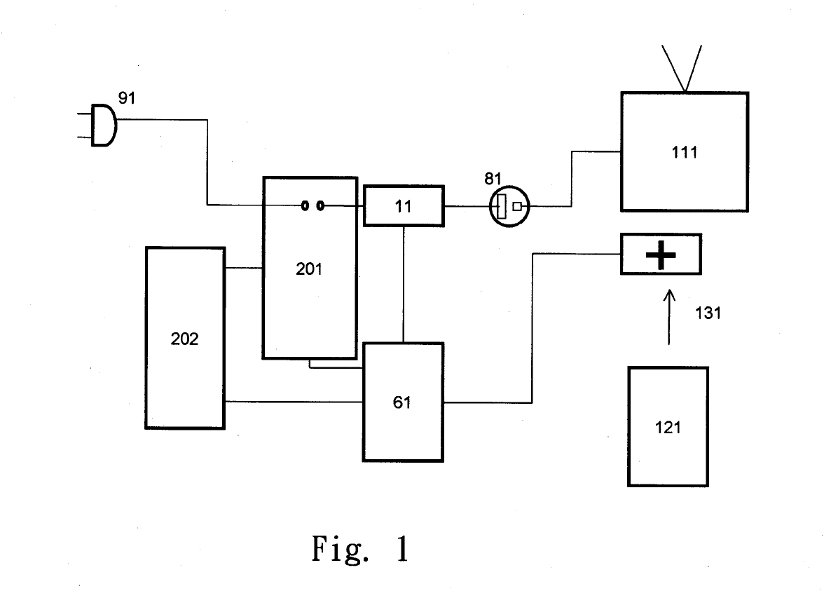

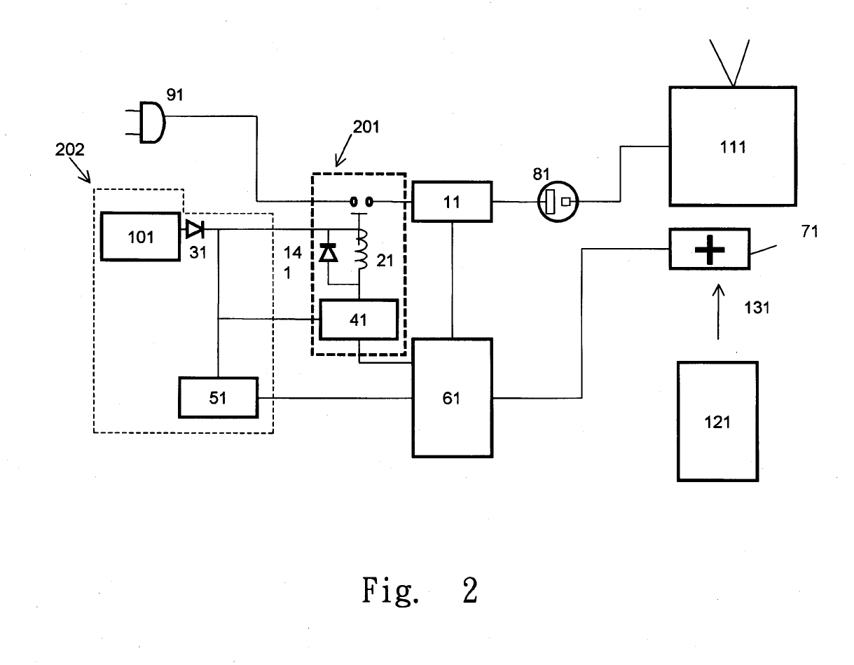

In the present invention, the structure of the present invention will be described with reference to the following FIGS. 1 and 2. FIG. 1 is a block diagram of the present invention and FIG. 2 shows the details about the element of the present invention.

A power source 202 is an independent power source or a dependent power source. The power source 202 may be a replaceable battery set 51 or a reusable battery set 51 or a solar plate 101 or the combination of above apparatus. Furthermore, the power source 202 may have power identical to the device 111 to be monitored, which can be converted by a power converter to the power source 202 of the present invention for supplying power to all the elements of the present invention. The power can be stored by a temporary battery which may be a chargeable battery or a capacitor. Then the power at this temporary battery can be further supplied to the present invention. In the present invention, it is illustrated that when a solar plate 101 is used, a diode 102 can be added at an output of the solar plate 101 for preventing power to reflow into the solar plate 101.

An AC power input 91 is connected to an external power source, such as a public power system for supplying power to the device 111 to be monitored.

A switchable AC power switch device 201 is connected to the AC power input 91 and has power supplied from the power source 202. The switchable AC power switch device 201 includes a switch unit 21 for switching AC power. The switch unit 21 may have a mechanical element, such as a relay, or a solenoid. The switch unit 21 may be a latch switch or a non-latch switch. A switch driving unit 41 is connected to the switch unit 21 for driving the switch unit 21. The switchable AC power switch device 201 may be formed electronically, such as being formed by a digital switch driving unit 41 and a power transistor switching circuit 21.

A current detector 11 serves for directly or indirectly detecting the current flow of from the AC power input 91 to the device 111 to be monitored. When the device 111 to be monitored is turned off in a standby mode. The current detector 11 will detect the status and thus the status signals to a logic electronic circuit 61. The detection of the current detector 11 may be formed by setting a low threshold, for example when the current is lower than a low threshold, the device 111 to be monitored determines that the device 111 to be monitored is in standby mode.

An AC (alternative current) power output end 81 is connected between the current detector 11 and the device 111 to be monitored for transferring current from the AC power input 91 to the device 111 to be monitored.

A logic electronic circuit 61 serves for determining the condition for the operation of the present invention. The logic electronic circuit 61 may be formed by programmable electronic elements or formed by lump electronic circuits for achieving the function of logic determination. When the logic electronic circuit 61 determines that the device 111 to be monitored is in standby state, it will emit a signal to the switchable AC power switch device 201 for turning off the AC power input 91.

A signal detecting transceiver 71 receives signals from the logic electronic circuit 61 by wired connection or wireless connection. The signal detecting transceiver 71 may detect signals from a far end remote controller 121 to the device 111 to be monitored and then signals will be transferred to the logic electronic circuit 61 from the signal detecting transceiver 71. The logic electronic circuit 61 will determine whether the device 111 to be monitored is turned on so as to turn on the switchable AC power switch device 201. When device 111 to be monitored is turned off and enters into a standby mode, the current detector 11 will generate a corresponding signal and will transfer the state to the logic electronic circuit 61. The detection of the standby mode can be achieved by a low threshold, for example when the current is lower than the low threshold, it will determine that the device 111 to be monitored is in a standby mode, and logic electronic circuit 61 will transmit a signal for turning off the AC power input 91 to the switch driving unit 41. Then the switch unit 21 will have power from the power source 202 and then isolates the AC power input 91 and the device 111 to be monitored so that the device 111 to be monitored will not further consume any power so as to achieve the object of power saving. Afterwards when the signal detecting transceiver 71 receives any signal 131 from the remote controller 121, the signal detecting transceiver 71 will generate a corresponding logic signal to the logic electronic circuit 61. When the logic electronic circuit 61 determines that the device 111 to be monitored will be turned on, the logic electronic circuit 61 will give a signal to the switch driving unit 41 to drive the switch unit 21. The switch unit 21 will reconnect the AC power input 91 and the device 111 to be monitored by using the power from the AC power input 91 directly or indirectly. Then the current detector 11 will detect the current state of the device 111 to be monitored and repeats above-mentioned process. The above mentioned auto-switching process not only saves more power in standby mode and it can detect the turn on signal from the remote controller 121 so as to automatically turn on the device 111 to be monitored. Moreover, the present invention is installed between the AC power input 91 and the device 111 to be monitored or is integrated into the device 111 to be monitored. In another embodiment of the present invention, the signal detecting transceiver 71 is a mechanical switch.

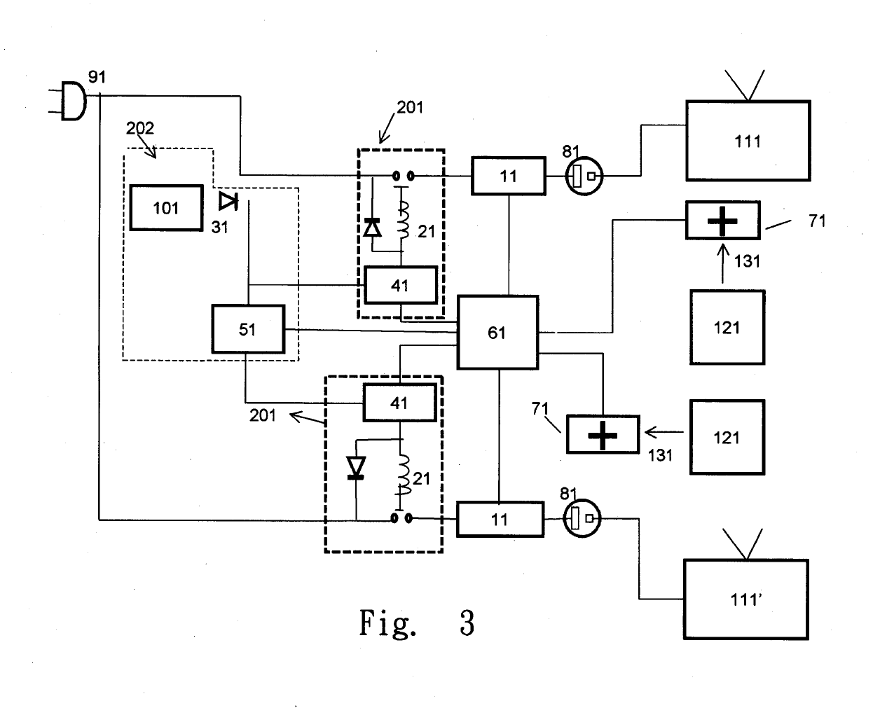

In FIG. 3, it is illustrated that the device of the present invention is used to more than two devices 111, 111′ to be monitored (two are shown in this embodiment). In this embodiment, the elements like the former embodiment are indicated with the same numerals. In this the present invention, it is illustrated that when the present invention is used to multiple devices 111 to be monitored, only the switchable AC power switch device 201, the AC power output end 81, the current detector 11 and the signal detecting transceiver 71 are necessary to have multiple sets.

Furthermore, when the present invention uses with a plurality of devices 111, 111′ to be monitored, the number of signal detecting transceivers 71 may be determined as required. It may be possible to use one signal detecting transceiver 71 to treat two devices 111, 111′ to be monitored.

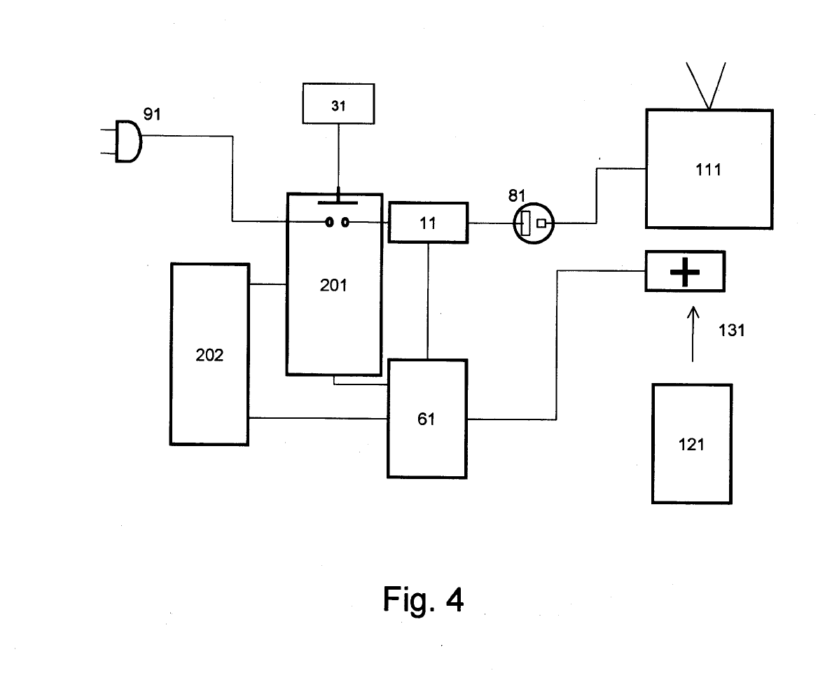

Referring to FIG. 4, the second embodiment of the present invention is illustrated. In this embodiment, a bypass switch 31 is connected across two ends to the switchable AC power switch device 201 so that when the bypass switch 31 is actuated, the switchable AC power switch device 201 will be bypassed so that the current from the AC power input 91 will directly flow to the device 111 to be monitored as an original switch without the function of auto-turn-on and auto-turn-off functions to the device 111 to be monitored.

Advantages of the present invention will be described herein. Firstly, the present invention causes the current consumption in standby mode will not occur so that no power consumption is in standby mode and thus power is saved. This is especially important in current high power cost age. Secondly, the present invention provides a function for auto-turning on an AC power without manually operation. Thus it is a power saving device with a practical usage. Thirdly, the present invention can turn off the AC power input automatically. Lastly, the device to be monitored is turned on by the current used remote controller 131 without needing manual operation.

The present invention is thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. An intellectual power saving switching assembly connected between an external AC power input and a device to be monitored for automatically turning on or turning off power supplied to the device to be monitored, comprising:
a power source supplying power to all elements of the switching assembly;
an AC power input connected to an external power source used to supplying power to the device to be monitored;
a switchable AC power switch device having a power input connected to the AC power input for interrupting power;
at least one current detector for detecting current flowing into the device to be monitored by direct detection or indirection detection; the current detector is connected to an output end of the switchable AC power switch device; when the device to be monitored is turned off and thus in a standby mode, the current detector will detect a corresponding standby signal and transmit the signal;
at least one AC power output end connected between the current detector and the device to be monitored for supplying power from the current detector to the device to be monitored;
a signal detecting transceiver for detecting an actuation signal from a remote controller to actuate the device to be monitored; and
a logic electronic circuit capable of receiving standby signals from the current detector and a far end actuation signals from the signal detecting transceiver so as to perform status determination for operating the switchable AC power switch device so as to interrupting or transfer the current from the AC power input to the device to be monitored.

2. The intellectual power saving switching assembly as claimed in claim 1, wherein the current detector determines the operation of the device to be monitored by using a current low threshold; if the current flowing through the current detector is lower than the low threshold, the logic electronic circuit determines that the device to be monitored is in a standby mode.
